(19) United States
(12) Patent Application Publication
(10) Pub. No.: US 2006/0157821 A1
(43) Pub. Date: Jul. 20, 2006

(54) Spray coating of cathode onto solid electrolyte capacitors

(76) Inventors: Guy C. VanNatta JR., Greenville, SC (US); Randolph S. Hahn, Simpsonville, SC (US); Chris W. Wayne, Spartanburg, SC (US); Kimberly L. Pritchard, Mauldin, SC (US); Keith R. Brenneman, Simpsonville, SC (US)

Correspondence Address: NEXSEN PRUETT JACOBS & POLLARD, 201 W MCBEE AVENUE, SUITE 400, GREENVILLE, SC, 29601, US

(21) Appl. No.: 11/370,762

(22) Filed: Mar. 8, 2006

Related U.S. Application Data
(62) Division of application No. 10/871,782, filed on Jun. 18, 2004.

(51) Int. Cl. H01L 29/00

(52) U.S. Cl. 257/532

(57) ABSTRACT

A process for forming a capacitor. The process includes the steps of forming an anode of a valve metal. A dielectric layer is formed on the valve metal. A conducting layer is formed on the dielectric layer wherein the conducting layer is the cathode. A carbon layer is sprayed onto the conducting layer and a silver layer is sprayed onto the on the conducting layer.

### BACKGROUND OF THE INVENTION

The present invention is related to an improved method of forming a solid electrolyte capacitor and an improved capacitor formed thereby. More specifically, the present invention is related to a spray method for forming the cathode and external conductive structure of a capacitor and the improved capacitor formed thereby.

The construction and manufacture of solid electrolyte capacitors is well documented. In the construction of a solid electrolytic capacitor a valve metal serves as the anode. The anode body can be either a porous pellet, formed by pressing and sintering a high purity powder, or a foil which is etched to provide an increased anode surface area. An oxide of the valve metal is electrolytically formed to cover all surfaces of the anode to serve as the dielectric of the capacitor. The solid cathode electrolyte is typically chosen from a very limited class of materials, to include manganese dioxide, intrinsically conductive polymers, and 7,7′,8,8′-tetracyanoquinonedimethane (TCNQ) a complex salt with conductive properties. The solid cathode electrolyte is applied so that it covers all dielectric surfaces. An important feature of the solid cathode electrolyte is that it can be made more resistive by exposure to high temperatures. This feature allows the capacitor to heal leakage sites due to Joule heating. In addition to the solid electrolyte the cathode of a solid electrolyte capacitor typically consists of several layers which are external to the body of the porous or etched anode body. In the case of surface mount constructions these layers typically include a carbon layer, a layer containing a highly conductive metal bound in a polymer or resin matrix with silver being most common, a conductive adhesive layer such as solder or a silver adhesive, and a highly conductive metal lead frame. It is important that the solid electrolyte be of sufficient buildup and density to prevent the overlaying layers from penetrating the solid electrolyte and contacting the dielectric. The reason for this is that these outer layers do not exhibit the healing properties required for a material which directly contacts the dielectric. Thus the ability to control the buildup, morphology, uniformity, and density of the solid electrolyte is critical to manufacturing a reliable solid electrolytic capacitor.

In the case of conductive polymer cathodes the conductive polymer is typically applied by either chemical oxidation polymerization or electrochemical oxidation polymerization with other less desirable techniques being reported.

In chemical oxidation polymerization the monomer, oxidizer and dopant are brought together and allowed to react to form conductive polymer, followed by a washing step to remove excess reactants and by-products of the reaction. Alternate chemical deposition involves first dipping a porous pellet or etched foil in an oxidizing solution and dopant, drying, and then dipping it into the monomer. The polymerization is allowed to occur under controlled conditions for a set time before the polymerization is ended with a wash step. This is repeated until the conductive polymer layer has the desired thickness. In a variation of this technique the anode is first dipped in a solution containing the monomer. The solvent is allowed to evaporate, followed by dipping in an oxidizer solution. Other variations include prolonging the second dip step to allow the polymerization reaction to occur in the dipping bath. These methods are ideally suited for coating the internal dielectric surfaces with a conductive polymer layer, but it is difficult to control the morphology of the external portion. Differences in anode porosity greatly affect the distribution, uniformity, and thickness of the external polymer layer. The external polymer layer is generally porous after the reaction by-products are removed by washing. It is also difficult to control the stoichiometry, which effects the conductivity of the polymer layer. It also involves many process steps. Carry over of monomer into the oxidizing solution, or vice versa, result in contamination of the second dipping solution which may require periodic change out of the solution.

Combined chemical deposition involves dipping a porous pellet or etched foil into a solution containing both the oxidizer and monomer. This process involves fewer steps and allows more control over the stoichiometry. The disadvantage of this process is that the monomer and ozidizer are allowed to react in the dipping solution, diminishing the supply of reactants and changing the composition and viscosity of the dipping solution over time. Methods proposed to control the reaction in the dipping solution are costly and complex. For example, Nishiyama et al., U.S. Pat. No. 5,455,736 describe a process for maintaining the dipping bath at cryogenic temperatures to slow the rate of reaction and prolong the life of the dipping bath.

Electrochemical oxidative polymerization has also been used to apply a conductive polymer layer to electrolytic capacitors. In this method an applied voltage drives the oxidation of the monomer to form polymer and the dopant is incorporated into the polymer from the electrolyte. The difficulty with this method is that the oxide dielectric has a high resistance, and so it is not therefore a suitable electrode for electrochemical oxidative polymerization. One way around this is to grow the oxide layer after forming the conductive polymer layer as described by Saiki et al., in U.S. Pat. No. 5,136,618. Although it is possible to grow a dielectric film beneath a conductive polymer film, the resulting dielectric film is of poor quality and not suitable for use in an electrolytic capcitor. Saiki et al., EP Appl. No. 0 501 805 A1 describe an alternative approach where the conductive polymer and dielectric oxide are grown simultaneously. The dielectric oxide grown in this manner is also of poor quality.

Harakawa et al., in U.S. Pat. No. 4,934,033 describe a method for passing current through the dielectric oxide and forming a conductive polymer coating on the dielectric oxide surfaces. However, this method requires very low temperature (−25° C.), non-aqueous electrolytes, is very difficult to control, and produces a polymer which is relatively low in conductivity. Due to the voltage drop inside the pores of the pellet or etched foil, this method will not coat internal dielectric surfaces with conductive polymer.

Another way to produce a conductive polymer layer on external dielectric surfaces by electrochemical polymerization is to first deposit a seed layer of conductive material such as manganese dioxide or conductive polymer deposited via chemical deposition methods such as described above on top of the oxide layer. A positive bias is applied to the conductive seeding layer via an external electrode which directly contacts the conductive seeding layer. The applied voltage drives the polymerization reaction. Fukuda et al., U.S. Pat. No. 4,780,796 describe this method where manganese dioxide is used as the seed layer. Tsuchiya et al., U.S. Pat. No. 4,943,892 describe a similar procedure using conductive polymer as the seed layer. This method is capable of forming dense, uniform, highly conductive films on the external dielectric surfaces of a porous pellet or etched foil anode. This requires contacting each anode at high costs and risk of damaging the dielectric layer.

Another method of applying an external conductive polymer layer is to dip a pellet or etched foil into a conductive polymer dispersion and then evaporate the solvent to directly deposit the polymer. The process can be repeated several times until the polymer is at the desired thickness. This process is simpler than other methods, but it has several disadvantages. First, the solid suspended polymer does not impregnate small pores well, decreasing its ability to attach to the internal cathode layer. Secondly, because available polymer dispersions have low percent solids and the morphology of the dried polymer is difficult to control, this process requires multiple dips. Successive dips risk dissolving applied polymer back into the polymer dispersion or softening of the applied polymer resulting in separation from the dielectric. Commercially available polymer dispersions tend not to cover edges and corners of the pressed pellet or etched foil. In order to better cover the edges higher viscosity formulations may be employed. However, higher viscosity dispersions deposit excess polymer on the flat surfaces of the anode, resulting in increased Equivalent Series Resistance (ESR). Since the conductive polymer dispersions do not penetrate the pores of the anode body the dispersion will not wick up the body of the anode. Thus in order to coat the top surfaces of the anode with the polymer the anode must be dipped beneath the surface of the dispersion. This produces a conductive polymer coating on the top of the anode and the lead wire. The conductive polymer must be removed from the lead wire prior to assembly operations used in the commercial production of electrolytic capacitors.

The carbon layer serves as a buffer between the solid electrolyte and the silver layer. The carbon formulation is optimized with respect to the particle size distribution of the carbon particles, the carbon to resin ratio, the type of resin employed, the type of carbon particle used (carbon flake, graphite, carbon black, etc.), solvent type and concentration. In addition physical properties that impact dipping operations, such as viscosity, have been optimized to provide a highly conductive carbon coating. In practice, a thicker carbon layer results in higher ESR since the conductive path length increases with carbon buildup. In order to reduce ESR capacitor manufacturers may reduce the viscosity of the carbon formulation. This results in an increased tendency of the carbon to penetrate through a porous polymer layer and contact the underlying dielectric resulting in electrical shorts. Incorporation of very fine carbon particles may increase the conductivity of the carbon layer, but increases the likelihood of carbon penetration through the solid electrolyte layer to the dielectric. Therefore, the artisan has had to optimize the carbon coating between the contradictory parameters of high ESR and high likelihood of failure due to electrical shorts. These conflicting desires have limited the furtherance of improvements in the ESR achievable due to the concurrent increases in failure rates with current technology.

The silver layer serves to conduct current from the lead frame around the anode to the sides not directly connected to the lead frame. The critical characteristics of this layer are high conductivity and adhesive strength to the carbon layer. Traditionally, the silver is applied via a dipping procedure very similar to carbon dipping. After dipping the silver may be blotted to remove excess silver from the bottom of the device. In order to improve the adhesive strength of the silver to the carbon lower silver to resin ratios can be used, but this reduces the conductivity of the silver layer. The composition of the resin can be optimized to improve the adhesive strength, but again conductivity of the silver layer typically suffers. In the case of pressed anode pellets capacitor manufacturers have developed fluted anodes with relatively narrow channels which increase the external surface area of the capacitor and reduce the path length from the outside of the porous anode body to the interior in order to reduce ESR. These narrow channels are difficult to coat uniformly with silver via dipping operations. It is also essential to coat as much of the external surface of the anode as possible with silver, yet avoid contact dielectric surfaces not coated with the solid electrolyte. Insufficient coverage of the solid electrolyte/carbon layers results in an increase in ESR. Short circuits, and a degradation in reliability, result when the silver extends beyond the solid electrolyte/carbon layers and directly contacts the dielectric.

Capacitor manufacturers typically apply carbon and silver to electrolytic capacitors using a dip process. Capacitor manufacturers have sought ways to improve the adhesive strength between the external layers of an electrolytic capacitor, but in so doing have continued to utilize dip methods. U.S. Pat. No. 6,556,427 discloses a method for increasing the adhesive strength between the carbon and conductive polymer layers. The method describes a particular structure of the conductive polymer layer having a lamellar structure with a space provided between the layers. Carbon is applied by dipping. The carbon is argued to penetrate the conductive polymer layer to such an extent that even the fine pores of the anode body are penetrated. Although the process described in U.S. Pat. No. 6,556,427 can lead to improved adhesive strength between the polymer and carbon layer, it can result in carbon penetrating to the dielectric surface resulting in short circuits and poor reliability.

U.S. Pat. No. 6,580,601 discloses a method for increasing the adhesive strength between the carbon and silver layer. A layer is proposed between the conventional silver layer and the carbon layer. The additional layer consist of a porous conductive silver layer and the carbon layer. The additional layer consists of a porous conductive paste made conductive by the incorporation of metal particles in a resin matrix. In a subsequent additional processing step the pores of the conductive paste layer are impregnated by dipping in a conductive polymer solution. This method adds an additional layer to the external cathode construction. Although the adhesive strength between the carbon and silver layer may be improved by this method, any additional layer results in an additional series resistance. The process also requires additional process steps resulting in increased manufacturing cost.

Equivalent Series Resistance (ESR) has become an increasingly important characteristic of capacitors used in many applications, including decoupling and filtering applications. To support this trend capacitor manufacturers have increased the conductivity of the solid electrolyte, optimized the carbon and silver formulations, converted to higher conductivity lead frame materials, and reduced the solid electrolyte and carbon layer thickness. It is important to provide electrolytic capacitors exhibiting ESR with excellent reliability at a low cost. Even with these advances the limit has been reached wherein further miniaturization and improvements in electrical circuitry have been thwarted. The desire is therefore for further decreases in ESR and further improvements in reliability. This ongoing desire has been further advanced by the present invention.

### SUMMARY OF THE INVENTION

It is an object of the present invention to provide uniform external cathode coatings on solid electrolytic capacitors with excellent control of the layer thickness.

It is another object of the present invention to coat the surfaces in narrow channels and edges of the external surfaces of a solid electrolytic capacitor.

It is yet another object of the present invention to reduce the equivalent series resistance (ESR) of a solid electrolytic capacitor without detriment to the reliability.

A particular feature of the present invention is improved reliability of the solid electrolytic capacitor without loss in ESR.

These and other advantages, as will be realized, are provided in a process for forming an electrolytic capacitor. The process includes the steps of forming an anode of a valve metal. A dielectric layer is then formed on the valve metal. A conducting layer is formed on the dielectric layer wherein the conducting layer is a cathode. A silver layer is then sprayed onto the conducting layer.

Yet another advantage is provided in a process for forming an electrolytic capacitor. The process includes the steps of forming an anode of a valve metal. A dielectric layer is formed on the valve metal. A conducting layer is formed on the dielectric layer wherein the conducting layer is the cathode. A carbon layer is sprayed onto the conducting layer and a silver layer is sprayed onto the conducting layer.

Yet another embodiment is provided in a process for forming an electrolytic capacitor. The process comprising the steps of a) forming an anode of a valve metal; b) forming a dielectric layer on the valve metal; c) spraying a conducting layer on the dielectric layer wherein the conducting layer is a cathode; and d) spraying a silver layer on the conducting layer.

Yet another embodiment is provided in a process for forming an electrolytic capacitor. The process comprises the steps of a) forming an anode of a valve metal, b) forming a dielectric layer on the valve metal, c) forming a conducting layer on the dielectric layer wherein the conducting layer is a cathode, c) spraying a carbon layer on the cathode, and d) forming a silver layer on the conducting layer.

Yet another embodiment is provided in a process for forming an electrolytic capacitor. The process comprises the steps of a) forming an anode of a valve metal, b) forming a dielectric layer on the valve metal, c) spraying a conducting layer on the dielectric layer wherein the conducting layer is a cathode and d) forming a silver layer on the conducting layer.

### BRIEF DESCRIPTION OF THE DRAWINGS

FIG. 1 is a schematic representation of a capacitor of the present invention.

FIG. 2 is a flow chart representation of the process of the present invention.

FIG. 3 illustrates fluted anodes wherein the left anode was dipped in silver and the right anode was sprayed with silver.

FIG. 4 illustrates a pair of anodes wherein the left anode was dipped in polymer dispersion and right anode was sprayed to form the polymer.

FIG. 5 illustrates a pair of anodes wherein the left anode was prepared by spraying a mixture of monomer and oxidizer wherein the right sample was prepared by chemical oxidative polymerization.

### DETAILED DESCRIPTION OF THE INVENTION

The present invention mitigates the deficiencies of the prior art by providing a method for applying a uniform, dense external solid electrolyte layer on solid electrolytic capacitors with excellent control of the layer thickness and placement. The present invention will be described with reference to the various figures which illustrate, without limiting, the invention. In the various figures similar elements are numbered accordingly.

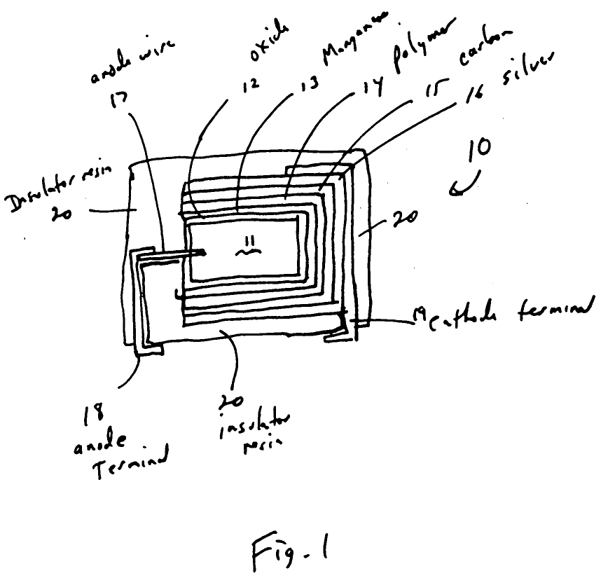

In FIG. 1, a cross-sectional view of a capacitor is shown as represented at 10. The capacitor comprises an anode, 11, comprising a valve metal as described herein. A dielectric layer, 12, is provided on the surface of the anode, 11. The dielectric layer is preferably formed as an oxide of the valve metal as further described herein. Coated on the surface of the dielectric layer, 12, is a conductive layer, 13. The conductive layer preferably comprises conductive polymer, TCNQ, manganese dioxide or combinations thereof. An optional carbon layer, 15, and silver layer, 16, are coated on the conducting layer, 14, to form an electrical contact between the conducting layer and the cathode terminal, 19. An anode wire, 17, provides electrical contact between the anode, 11, and an anode terminal, 18. The entire element, except for the terminus of the leads, is then preferably encased in a housing, 20, which is preferably an epoxy resin housing.

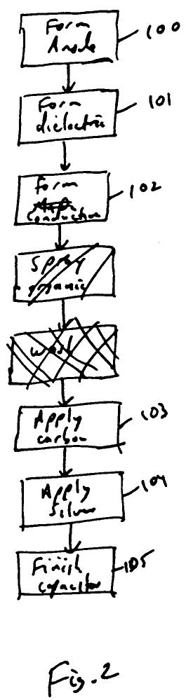

The process for forming the capacitor is illustrated in FIG. 2.

Referring to FIG. 2, the anode is formed, 100, of a valve metal as described further herein.

The valve-metal is preferably niobium, aluminum, tantalum, titanium, zirconium, hafnium, tungsten and alloys or combinations thereof. Aluminum, tantalum and niobium are most preferred. Aluminum is typically employed as a foil while tantalum is typically prepared by pressing tantalum powder and sintering to form a compact. For convenience in handling, the valve metal is typically attached to a carrier thereby allowing large numbers of elements to be processed at the same time.

The valve metal is preferably etched to increase the surface area particularly if the valve metal is a foil such as aluminum foil. Etching is preferably done by immersing the valve metal into at least one etching bath. Various etching baths are taught in the art and the method used for etching the valve metal is not limited herein.

A dielectric is formed, 101, on the exterior of the valve metal. It is most desirable that the dielectric layer be an oxide of the valve metal. The oxide is preferably formed by dipping the valve metal into an electrolyte solution and applying a positive voltage to the valve metal. Electrolytes for the oxide formation can include ethylene glycol as described in U.S. Pat. No. 5,716,511; alkanolamines and phosphoric acid, as described in U.S. Pat. No. 6,480,371; polar aprotic solvent solutions of phosphoric acid as described in U.K. Pat. No. GB 2,168,383 and U.S. Pat. No. 5,185,075; complexes of polar aprotic solvents with protonated amines as described in U.S. Pat. No. 4,812,951 or the like. Electrolytes for formation of the oxide on the valve metal include aqueous solutions of dicarboxylic acids, such as ammonium adipate are also known. Other materials may be incorporated into the oxide such as phosphates, citrates, etc. to impart thermal stability or chemical or hydration resistance to the oxide layer.

A conductive layer is formed, 102, on the surface of the oxide. The conductive layer acts as the cathode of the capacitor. The conductive layer preferably comprises a conductive polymer and may include a manganese dioxide layer between the conductive polymer layer and the dielectric. When used, the manganese dioxide layer is preferably deposited on the dielectric oxide layer and the conductive polymer layer is formed thereon. The manganese dioxide layer is preferably obtained by immersing an anode element in an aqueous manganese nitrate solution. The manganese oxide is then formed by thermally decomposing the nitrate at a temperature of from 250° to 350° C. in a dry or steam atmosphere. The anode may be treated multiple times to insure optimum coverage.

The conducting polymer is preferably chosen from polypyrroles, polyanilines, polythiophenes and polymers comprises repeating units of Formula I, particularly in combination with organic sulfates: 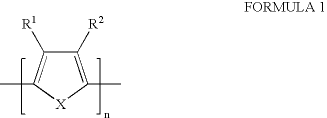
wherein R¹ and R² are chosen to prohibit polymerization at the beta-site of the ring and x is S, Se or N.

A particularly preferred polymer is 3,4-polyethylene dioxythiophene (PEDT).

The polymer can be applied by spraying a solution of oxidizer and dopant and simultaneously a solution of monomer onto the pellet or foil, allowing the polymerization to occur for a set time, and ending the polymerization with a wash. The oxidizer, dopant and monomer may be sprayed as one solution. It is most preferred the solutions be sprayed in an amount sufficient to provide an excess of monomer. If an excess of monomer is not used an uncharacterized salt forms which is highly undesirable. Because the spray is mostly liquid reagents as opposed to solid polymer, it may be able to penetrate the pores and bond to the internal layer better than a polymer dispersion. Since the reagents can be mixed in small quantities as they are being sprayed, there is little waste of reagents and change in composition due to premature polymerization. Finally, stoichiometry can be easily controlled by controlling the flow rates, concentration or both. Alternatively, a polymer dispersion or slurry can be applied via a spray method. Contrasted with the advantages and disadvantages of traditional methods of applying an external solid electrolyte layer spraying offers many advantages. The combination of dipping and spraying may be preferred. Spraying of a polymer slurry after dipping in a polymer slurry may be preferred.

The advantages of spraying polymer includes the ability to control polymer uniformity, morphology and buildup. Minimum raw materials are used and the raw materials can be mixed at use as opposed to the necessity of preparing a sufficient batch size to have an adequate volume for dipping. A dense polymer layer can be formed and the ability to cover the edges is greatly enhanced.

After conductive layer formation, 102, a carbon layer may be applied, 103, preferably by spraying. Spraying carbon allows excellent control of carbon buildup without the need to dip in low viscosity carbon suspensions. Since the carbon is essentially dry as it contacts the solid electrolyte layer the carbon does not penetrate to the dielectric layer. This allows the use of very fine carbon particles in the carbon formulation without the risk of carbon penetration to the dielectric. The ability to apply a very thin carbon layer containing very fine carbon particles greatly reduces ESR. Since there is minimal risk of carbon penetrating through the solid cathode electrolyte the occurance of shorts is reduced and reliability is increased relative to traditional dipping methods. Spraying carbon onto a still wet polymer layer allows an intermingling of the outer most solid electrolyte layer and the carbon layer resulting in improved adhesive strength of the interface and lower ESR. Carbon solutions typically employed for a dip process are suitable for use with a spray process. A particularly preferred carbon spray solution is carbon in isobutylacetate.

A silver layer is applied, 104, to form an electrical contact between the cathode and cathode terminal. Spraying silver onto carbon provides superior adhesive strength, relative to dipping, resulting in lower ESR. Since no blotting is necessary less silver is used thereby reducing cost. It is another object of this invention to coat the surfaces in narrow channels and edges of the external surfaces of a solid electrolytic capacitor which are difficult to coat via dipping methods. Spraying silver also allows for better control of the placement of the silver, allowing for the lowest possible ESR without sacrificing reliability or increasing the incidence of short circuits. Spraying silver onto a partially wet layer allows an intermingling of the two layers resulting in a further improvement in adhesive strength of the interface and still lower ESR.

The capacitor is finished, 105, by incorporating anode and cathode terminals and external insulators as known in the art.

The spray apparatus used in the following examples was a Paasche H-3 external mix siphon-feed air brush with air pressure at 50 psi for silver and polymer and 15 psi for carbon. The spray was at a compound angle of 45° relative to the face of the anode and 45° relative to the top of the anode and 3 inches from the anode surface. The anodes were sprayed in a spray booth opened on the front side with a rear exhaust with an air flow of 70 ft³ per minute. The anodes were suspended from a carrier bar with a fixture holding the bar inverted and masking the lead wires from the spray. Consecutive passes were made across the carrier bar with the air brush at the angles specified above, each pass beginning with a different end and side of the carrier bar. The speed of the air brush movement relative to the bar was about 2 inches per second. For the silver four passes were made, for the carbon five passes were made and for the polymer eight passes were made.

While not limited to any theory, rapid drying of the polymer layer is hypothesized to reduce the propensity for polymer pulling away from the previous layer particularly at the edges and corners. With an aqueous polymer multiple passes of low volume spray are believed to allow rapid drying and are therefore preferred over fewer passes with higher volumes of spray. With more volatile solvents this may not be necessary.

In the examples that follow the polymer solution comprised PEDT and the oxidizer was ferric toluene sulfonate. Ferric toluene sulfonate is preferred since it functions both as an oxidizer and dopant.

### EXAMPLES

### Example 1

Commercially available capacitor grade tantalum powder was pressed into a pellet 0.133×0.190×0.034 inches (3.38×4.83×0.864 mm) and sintered to form a batch of anodes. The dielectric oxide layer was formed by applying 7.5 volts in an aqueous phosphoric acid electrolyte. The dielectric surfaces were coated with intrinsically conductive PEDT using a chemical oxidation dip process. A matrix experiment was run comparing ESR of carbon dip vs. carbon spray and silver dip versus silver spray. The data, provided in Table 1, indicates that ESR was lower with carbon spray than carbon dip with an average ESR improvement of 0.84 milliohms. The average ESR was lower for silver spray than for a silver dip by an average of 2.54 milliohms. The lowest ESR was obtained when both carbon and silver were sprayed which is represented as a 3.43 milliohm improvement in ESR versus both layers formed by dipping.

TABLE 1
ESR results for Example 1 (milliohms)

| | Silver Dip | Silver Spray | Average (Carbon) |
|---|---|---|---|
| Carbon Dip | 14.48 | 11.51 | 12.95 |
| Carbon Spray | 13.17 | 11.05 | 12.11 |
| Average (Silver) | 13.82 | 11.28 | |

### Example 2

Commercially available capacitor grade tantalum powder was pressed into a pellet 0.133×0.190×0.034 inches (3.38×4.83×0.864 mm) and sintered to form a batch of anodes. The dielectric oxide layer was formed by applying 9.0 volts in an aqueous phosphoric acid electrolyte. The dielectric surfaces were coated with an intrinsically conductive polymer PEDT using a chemical oxidation dip process. Carbon was applied by dipping in a carbon suspension. Four randomized samples were pulled and silver was applied to two samples by dipping and two samples by spraying. The four groups were encapsulated with a thermoset epoxy using a transfer molding process. Subsequent to the molding operation the four groups were passed through an infrared oven to simulate the process by which the components are mounted to a circuit board. ESR was measured after encapsulation and after the infrared pass. The results are summarized in Table 2.

TABLE 2
ESR results for Example 2

| | ESR after | ESR after | ESR increase | Silver |
|---|---|---|---|---|
| | Encapsulation | IR pass | at IR | buildup |
| | (milliohms) | (milliohms) | (milliohms) | (microns) |
| Silver dip | 9.45 | 15.25 | 5.80 | 65 |
| Medium Silver | 14.32 | 16.54 | 2.22 | 5 |
| Spray (4 | | | | |
| passes) | | | | |
| Heavier Silver | 13.27 | 15.40 | 2.13 | 7 |
| Spray (8 | | | | |
| passes) | | | | |
| Medium silver | 9.14 | 11.91 | 2.77 | 37 |
| spray plus | | | | |
| silver dip | | | | |

The data in Table 2 indicates that ESR, after encapsulation, was greatly impacted by silver buildup. The two groups with silver spray alone had very little silver buildup, resulting in elevated ESR after encapsulation. The fourth cell which added a silver dip after the silver spray indicates that the higher ESR, after encapsulation, was due to thin silver, not the spray process itself. All groups with silver spray exhibit considerably lower increase in ESR during the infrared pass.

### Example 3

Nine random samples were pulled from a batch of 0.133×0.190×0.034 inches (3.38×4.83×0.864 mm) pellet anodes after application of conductive polymer PEDT, by a chemical oxidation process, to demonstrate the relationship between carbon buildup and ESR. Carbon solutions are commercially available from various vendors. The data indicates that ESR was proportional to carbon buildup and that the thinnest carbon layers were obtained by spraying the carbon. Elimination of the carbon layer resulted in higher ESR due to the incompatibility of the conductive polymer/silver interface as indicated in Table 3.

TABLE 3
ESR and Carbon Thickness (microns)

| Application Process | ESR (milliohms) | Thickness (micron) |
|---|---|---|
| No Carbon | 10.04 | 0 |
| Thin Spray Coat (2 passes) | 7.21 | 0.90 |
| Medium Spray Coat (4 passes) | 7.33 | 0.95 |
| Thick Spray Coat (8 passes) | 7.41 | 1.15 |
| 1 dip, sponge blot | 7.55 | 1.81 |
| 1 dip, single vacuum | 7.75 | 2.64 |
| 1 dip, double vacuum | 7.96 | 3.05 |
| 1 dip, no blot | 8.49 | 5.63 |
| 3 dips, no blt | 14.42 | 21.95 |
| 5 dips, no blot | 25.88 | 54.75 |

### Comparative Example

Anodes were pressed to 0.133×0.190×0.035 inch (3.38×4.83×0.864 mm) dimension employing a 42,000 CV/g powder. The anodes were processed through standard sintering, dielectric formation, conductive polymer application process steps. Following the application of the external conductive polymer layer the lot was split into two random groups. A control group was dipped in commercial carbon formulation with a viscosity of 50 cps. The inventive group was dipped in a lower viscosity, 15 cps, carbon. As expected the carbon buildup on the external polymer was less for the lower viscosity carbon. This corresponded with lower ESR. However, the thinner carbon penetrated through the external polymer more readily resulting in shorts at surface mount testing. The correlation between lower viscosity carbon provided a thinner carbon coat with lower ESR but at a cost of increased incidence of surface mounting test failures has been demonstrated in several experiments. The data from this experiment are summarized in Table 4.

TABLE 4
Capacitor properties as a function of carbon solution viscosity.

| | Carbon Solution | | |
|---|---|---|---|
| Group | Viscosity (cps) | ESR (milliohms) | SMT shorts (ppm) |
| Control | 50 | 11.9 | 0 |
| Inventive | 15 | 9.7 | 1471 |

### Example 4

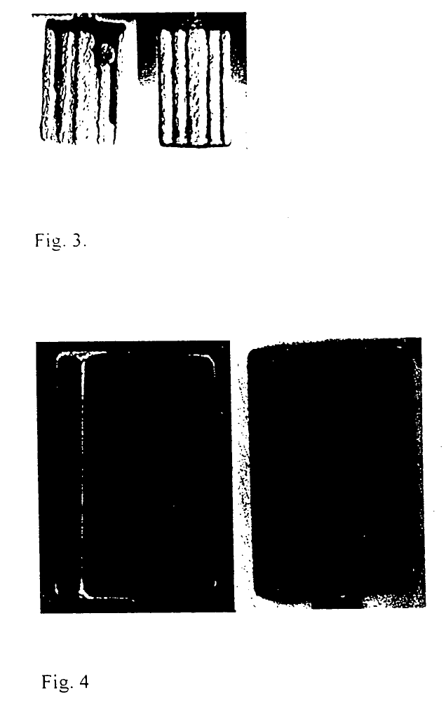

An identical set of 0.133×0.191×0.038 inch (3.38×4.83×0.864 mm) fluted anodes were prepared with four channels approximately 0.016 inches (0.406 mm) in width and 0.009 inches (0.229 mm) in depth. They were processed identically and simultaneously for all process steps except for the application of the silver layer. The silver was applied to one sample using a dipping method and on the other sample with a spraying method. Both samples are shown in FIG. 3 with the left sample being the dipped sample and the right sample being the sprayed sample. The sprayed sample illustrates improved coverage of the channels and upper extent of the anode as well as higher uniformity of the coating.

### Example 5

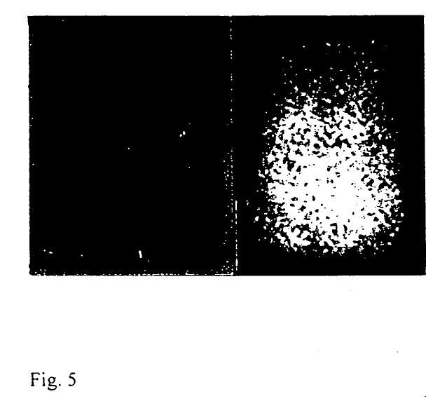

Two identical anodes were processed in the same manner except for the method of applying an external polymer cathode layer. Both anodes were 0.122×0.170×0.028 inches (3.10×4.32×0.711 mm) were processed at approximately 61,000 CV/g at a press density of 5.5 g/cm³. scanning electron microscope backscatter photos obtained of the two samples are provided in FIG. 4. In FIG. 4, the left anode has the polymer dispersion applied by the dipping process while the anode on the right had the polymer applied by the spray method. It is clear from the photos that the spray method provides better edge and corner coverage than the dip process. The sample wherein the polymer was applied with a spray process had a leak current of 4.49 microamps while the sample prepared by the polymer dip process had a leak current of 103.1 microamps.

### Example 6

Two anodes with dimensions of 0.122×0.170×0.028 inches (3.10×4.32×0.711 mm) were pressed with powder of approximately 61,000 CV/g with a 5.5 g/cm³ press density. Both were processed through formation and through three internal polymerization steps to form the internal cathode layer. SEM backscatter photographs are provided in FIG. 5. In FIG. 5 the anode on the left has an external conductive polymer coating applied by spraying a mixture of the monomer and oxidizer. The anode on the right had conductive polymer applied via a chemical oxidative polymerization process. This example clearly demonstrates that the polymer applied to the face of the anode by the spraying process is superior to the process applied by chemical oxidative polymerization process.

### Example 7

Example 3 was repeated with the exception of one sample being sprayed with carbon prior to the polymer dispersion drying and the other sprayed after the polymer dispersion as allowed to dry. The ESR for the sample with carbon spray on dry polymer dispersion was 31 milliohms while the ESR for the sample with carbon spray on wet polymer dispersion was 24 milliohms indicating improvements in the layer interface.

The present invention has been described with particular reference to the preferred embodiments and representative examples. One of skill in the art, upon reviewing and duplicating the results presented herein, may arrive at additional embodiments, alterations and conclusion which are within the meets and bounds of the present invention which is more explicitly set forth in the claims appended hereto.

1-11. (canceled)

12. A capacitor formed by the process of
forming an anode of a valve metal;
forming a dielectric layer on said valve metal;
forming a conducting layer on said dielectric layer wherein said conducting layer is a cathode; and
spraying a silver layer on said conducting layer.

13-21. (canceled)

22. A capacitor formed by the process of
forming an anode of a valve metal;
forming a dielectric layer on said valve metal;
forming a conducting layer on said dielectric layer wherein said conducting layer is a cathode;
spraying a carbon layer on said conducting layer; and
spraying a silver layer on said conducting layer.

23-24. (canceled)

25. The process for forming an electrolytic capacitor comprising the steps of:
forming an anode of a valve metal;
forming a dielectric layer on said valve metal;
spraying a conducting layer on said dielectric layer wherein said conducting layer is a cathode; and
spraying a silver layer on said conducting layer further comprising applying a carbon layer between said spraying a conducting layer and spraying a silver layer wherein said carbon layer is formed by spraying said carbon layer onto said cathode.

26. The process for forming an electrolytic capacitor comprising the steps of:
forming an anode of a valve metal;
forming a dielectric layer on said valve metal;
spraying a conducting layer on said dielectric layer wherein said conducting layer is a cathode; and
spraying a silver layer on said conducting layer wherein said conducting layer comprises a polymeric layer.

27. The process for forming an electrolytic capacitor of claim 26 comprising spraying a polymer suspension to form said polymeric layer.

28. The process for forming an electrolytic capacitor of claim 27 further comprising dipping in a polymer suspension.

29. The process for forming an electrolytic capacitor of claim 26 wherein said spraying a conducting layer comprises spraying a monomer solution.

30. The process for forming an electrolytic capacitor of claim 29 wherein said monomer solution further comprises dopant and oxidizer.

31. The process for forming an electrolytic capacitor of claim 30 wherein said monomer is in a stoichometric excess.

32. The process for forming an electrolytic capacitor of claim 27 wherein said spraying a conducting layer comprises spraying a polymer solution.

33. The process for forming an electrolytic capacitor of claim 32 further comprising dipping in a polymer solution.

34. The process for forming a capacitor comprising the steps of:
forming an anode of a valve metal;
forming a dielectric layer on said valve metal;
spraying a conducting layer on said dielectric layer wherein said conducting layer is a cathode; and
spraying a silver layer on said conducting layer further comprising applying a carbon layer between said spraying a conducting layer and spraying a silver layer wherein said spraying of said silver is done prior to drying said carbon layer.

35. A capacitor formed by the process comprising the steps of:
forming an anode of a valve metal;
forming a dielectric layer on said valve metal;
spraying a conducting layer on said dielectric layer wherein said conducting layer is a cathode; and
spraying a silver layer on said conducting layer.

36-48. (canceled)

49. A capacitor formed by the process comprising the steps of:
forming an anode of a valve metal;
forming a dielectric layer on said valve metal;
forming a conducting layer on said dielectric layer wherein said conducting layer is a cathode;
spraying a carbon layer on said cathode; and
forming a silver layer on said conducting layer.

50-62. (canceled)

63. A capacitor formed by the process comprising the steps of:
forming an anode of a valve metal;
forming a dielectric layer on said valve metal;
spraying a conducting layer on said dielectric layer wherein said conducting layer is a cathode;
forming a silver layer on said conducting layer.
